(19) United States
(12) Patent Application Publication
(10) Pub. No.: US 2015/0255485 A1
(43) Pub. Date: Sep. 10, 2015

(54) NONVOLATILE SEMICONDUCTOR STORAGE DEVICE

(71) Applicant: KABUSHIKI KAISHA TOSHIBA, Minato-ku (JP)

(72) Inventors: Hisashi KAMEOKA, Yokkaichi (JP); Daigo ICHINOSE, Nagoya (JP)

(73) Assignee: KABUSHIKI KAISHA TOSHIBA, Minato-ku (JP)

(21) Appl. No.: 14/638,265

(22) Filed: Mar. 4, 2015

(30) Foreign Application Priority Data
Mar. 5, 2014 (JP) 2014-042736

(51) Int. Cl. H01L 27/115; H01L 29/45; H01L 29/49; H01L 29/06

(52) U.S. Cl. CPC H01L 27/11582; H01L 27/11524; H01L 27/11556; H01L 27/1157; H01L 29/0649; H01L 29/456; H01L 29/4916

(57) ABSTRACT

A nonvolatile semiconductor storage device includes a semiconductor substrate; a stack structure disposed above the substrate and including insulation layers and conductive layers stacked alternatively; and a select gate electrode layer disposed above the stack structure; holes extending through the stack structure and the electrode layer; a connecting portion connecting lower portions of adjacent holes; and a pillar insulating film and semiconductor pillars disposed in the connected holes and in the connecting portion. A back gate is disposed between a portion above the connecting portion and the stack structure. An isolation trench is disposed between the adjacent and connected pillars to isolate the stack structure and the electrode layer. The trench has a bottom portion contacting the back gate. A bottom surface of the trench is lower than an upper surface of the back gate. A metal silicide is disposed in a portion where the back gate contacts the trench.

### CROSS-REFERENCE TO RELATED APPLICATION(S)

This application is based upon and claims the benefit of priority from Japanese Patent Application No. 2014-042736, filed on, Mar. 5, 2014 the entire contents of which are incorporated herein by reference.

### FIELD

Embodiments disclosed herein generally relate to a nonvolatile semiconductor storage device.

### BACKGROUND

NAND flash memory is one example of a nonvolatile semiconductor storage device. In some NAND flash memories, transistors are disposed three dimensionally in a pillar structures for example. The pillar structures are provided with a connecting portion at their lower portions. The connecting portion is surrounded by a back gate which controls the conductivity of the connecting portion. The back gate is typically formed of a silicon layer and thus, exhibits high resistance which may increase the drive voltage.

### BRIEF DESCRIPTION OF THE DRAWINGS

FIG. 1 pertains to a first embodiment and is one example of a perspective view partially illustrating a memory cell region provided in a nonvolatile semiconductor storage device.

FIG. 2 is one example of a vertical cross sectional view illustrating a cross-sectional structure taken along line A-A of FIG. 1.

FIGS. 3, 4, 5, 6, 7, 8, 9, 10, 11, 12, 13, and 14 pertain to the first embodiment and are examples of vertical cross-sectional views illustrating the manufacturing method of the nonvolatile semiconductor storage device.

### DETAILED DESCRIPTION

An embodiment of a semiconductor storage device is provided with a semiconductor substrate; a stack structure disposed above the semiconductor substrate and including a plurality of insulation layers and conductive layers stacked alternatively above one another; a select gate electrode layer disposed above the stack structure; a plurality of holes extending through the stack structure and the select gate electrode layer; a connecting portion connecting lower portions of adjacent holes among the plurality of holes; a pillar insulating film and semiconductor pillars disposed in the holes being connected by the connecting portion and in the connecting portion; a back gate disposed between a portion above the connecting portion and the stack structure; an isolation trench disposed between the semiconductor pillars being adjacent to and connected to one another so as to isolate the stack structure and the select gate electrode layer, the isolation trench having a bottom portion contacting the back gate, a bottom surface of the isolation trench being lower than an upper surface of the back gate; and a metal silicide disposed in a portion where the back gate contacts the isolation trench.

### Embodiments

Embodiments are described hereinafter with reference to the drawings. The drawings are schematic and thus, are not necessarily consistent with the actual correlation of thickness to planar dimensions and the actual thickness ratios between each of the layers. The same element may be represented in different dimensions or ratios depending upon the figures. Further, directional terms such as up, down, left, and right are used in a relative context with an assumption that the surface, on which circuitry is formed, of the later described semiconductor substrate faces up. Thus, the directional terms do not necessarily correspond to the directions based on gravitational acceleration. In the drawings referred to in the following description, elements that are identical or similar to those already illustrated are identified with identical or similar reference symbols and may not be re-described in detail. In the following description, XYZ orthogonal coordinate system is used for convenience of explanation. In the coordinate system, the X direction and the Y direction each indicates a direction parallel to the surface of a semiconductor substrate and crosses orthogonally with one another. The direction crossing orthogonally with both the X and the Y direction is referred to as the Z direction. Further, the term “stack” or “stacking” is used in the description to indicate multiple layers being directly disposed one over the other or being disposed one over the other with an intervening element disposed therebetween.

### First Embodiment

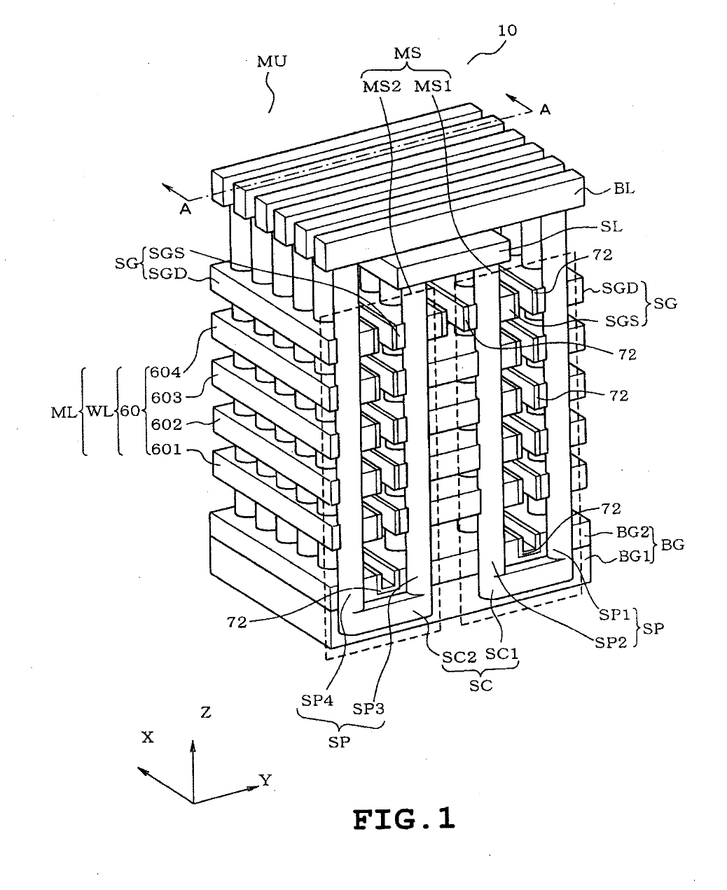

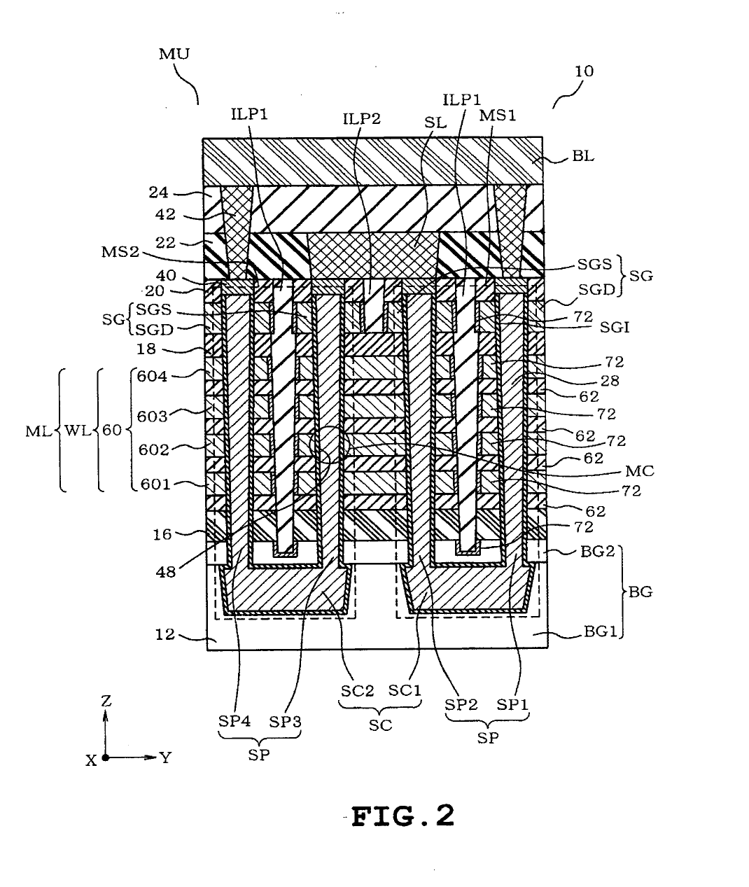

FIG. 1 is one example of a perspective view partially illustrating the structure of a memory-cell region of nonvolatile semiconductor storage device 10 of the present embodiment. FIG. 2 is one example of a vertical cross-sectional view schematically illustrating the cross-sectional structure taken along line A-A of FIG. 1. FIG. 1 only illustrates the conductive portions for good visibility and does not illustrate the insulating portions. Nonvolatile semiconductor storage device 10 of the present embodiment is described through an example of a three-dimensional NAND flash memory shaped like a letter U. More specifically, nonvolatile semiconductor storage device 10 is provided with memory string MS shaped like a letter U which is configured by connecting the bottom portions of adjacent semiconductor pillars SP.

As illustrated in FIG. 1 and FIG. 2, lower back gate BG1 and upper back gate BG2 are provided in the surface of semiconductor substrate 12. Back gate BG1 is formed for example by doping impurities into semiconductor substrate 12. Connecting portion SC, connecting the lower portions of later described semiconductor pillars SP, is provided in back gate BG1. Back gate BG1 is formed so as to surround the lower portion and the side portion of connecting portion SC. Back gate BG2 is formed so as to cover the upper portion of connecting portion SC. Back gate BG2 is formed of for example an amorphous silicon doped with impurities. Back gate BG1 and back gate BG2 are hereinafter collectively referred to as back gate BG. Back gate BG covers the periphery, i.e. the lower portion, the upper portions and the side portion, of connecting portion SC by the cooperation of back gate BG1 and back gate BG2.

A silicon substrate may be used for example as semiconductor substrate 12. For example, elements not illustrated may be formed in a silicon substrate and the upper portions of the elements may be covered by an insulating film. After planarizing the upper surface of the insulating film, an amorphous silicon layer for example may be formed above the insulating film. In such case, back gate BG and connecting portion SC are formed in the amorphous silicon layer.

Stopper insulating film 16 is formed above back gate BG. Stopper insulating film 16 maybe formed of tantalum oxide (TaO) for example.

Stack structure ML is formed above the above described structure. Stack structure ML is provided with a plurality of electrode films 60 (stacked in the sequence of 601 to 604 from the lower layer) and a plurality of interelectrode insulating films 62 stacked alternately in the Z direction as viewed in the figures. The term “electrode film 60” is used hereinafter when not specifying an individual electrode film 60 and terms “electrode film 601, 602, 603, and 604” are used when specifying an individual electrode film 60.

Electrode film 60 is shaped like a belt extending along the X direction as viewed in the figures (the front and rear direction extending into the page of FIG. 2). Electrode film 60 serves as word line WL of nonvolatile semiconductor storage device 10 of the present embodiment. An amorphous silicon rendered electrically conductive by introducing impurities or polysilicon (polycrystalline silicon) rendered electrically conductive by introducing impurities, or the like may be used as electrode film 60. Boron (B) may be used for example as impurities.

Interelectrode insulating film 62 provides insulation and isolation between the stack of electrode films 60. Four layers of electrode films 60 are formed in this example; however it is possible to form any number of layers of electrode films 60. Multiples of eight are frequently employed number of films for electrode films 60; however, dummy layers may be provided for example further thereabove. A silicon oxide film maybe used for example as interelectrode insulating film 62.

Select gate electrode SG is disposed above (that is, above stack structure ML) the electrode film 60 (604) in the uppermost layer via interlayer insulating film 16. Select gate electrode SG is shaped like a belt extending along the X direction as viewed in the figures (the front and rear direction extending into the page of FIG. 2). The transistor configured by select gate electrode SG serves as a switching transistor controlling the selection/non-selection of later described memory string MS. A silicon oxide film may be used for example as interlayer insulating film 18. An amorphous silicon rendered electrically conductive by introducing impurities or polysilicon (polycrystalline silicon) rendered electrically conductive by introducing impurities, or the like may be used as select gate electrode SG.

Nonvolatile semiconductor storage device 10 is provided with semiconductor pillar SP penetrating interlayer insulating film 18, stack structure ML, and select gate electrode SG in the Z direction. The term “semiconductor pillar SP” is used hereinafter when not specifying an individual semiconductor pillar illustrated in the figures, and terms “semiconductor pillars SP1, SP2, SP3, and SP4” are used when specifying an individual semiconductor pillar.

Pillar insulating film 28 and semiconductor pillar SP are formed for example by filling a hole extending in the Z direction through stack structure ML and select gate electrode SG. Semiconductor pillar SP may be formed in the shape of a cylinder (circular cylinder) or column (circular column) extending in the Z direction. Semiconductor pillar SP serves as a channel portion of a transistor. The central portion of semiconductor pillar SP may be hollow or may be filled with an insulating film.

A stack film, having first silicon oxide film (SiO₂)/silicon nitride film (SiN)/second silicon oxide film (SiO₂) stacked inward from the inner wall surface of semiconductor pillar SP, maybe used as pillar insulating film 28. First silicon oxide film serves as a block film. Silicon nitride film serves as a charge film. Second silicon oxide film serves as a tunnel film. An amorphous silicon for example may be used as a semiconductor film forming semiconductor pillar SP. Semiconductor pillar SP serves as a channel portion of a transistor. Pillar insulating film 28 serves as storage layer 48 of memory cell MC and as a gate oxide film of a memory cell transistor. Further, pillar insulating film 28 serves as select gate insulating film SGI of select gate electrode SG. Electrode film 60 (word line WL) serves as the gate electrode of the memory cell transistor.

The term “connecting portion SC” is used hereinafter when not specifying an individual connecting portion illustrated in the figures, and terms “connecting portions SC1 and SC2” are used when specifying an individual connecting portion. The term “memory string MS” is used hereinafter when not specifying an individual memory string, and terms “memory strings MS1 and MS2” are used when specifying an individual memory string.

Semiconductor pillars SP are disposed in the order of SP1, SP2, SP3, and SP4 from the Y direction right side of the figures. Semiconductor pillars SP1 to SP4 extend in the Z direction through stack structure ML.

The lower portions of adjacent semiconductor pillars SP1 and SP2 are connected by connecting portion SC1 to form a single memory string MS1. The lower portions of adjacent semiconductor pillars SP3 and SP4 are connected by connecting portion SC2 to form a single memory string MS2. The interior of connecting portion SC is structurally the same as semiconductor pillar SP. The interior of connecting portion SC can be rendered electrically conductive by applying voltage to back gate 55.

Memory cell transistors are formed at the portion where electrode films 60 (601 to 604) and semiconductor pillar SP (SP1 to SP4) intersect. Storage layer 48 is provided between semiconductor pillar SP serving as the channel portion of the memory cell transistors and electrode film 60. Storage layer 48 may use the film used for pillar insulating film 28. The memory cell transistor is aligned in a three-dimensional matrix. Each of the memory cell transistors serves as memory cell MC in which information (data) is stored by accumulating charge in storage layer 48. In each of memory cell MC, storage layer 48 accumulates or releases charge by the electric field applied between semiconductor pillar SP and electrode film 60 and serves as a charge storage layer (information storage portion).

Interlayer insulating film 20 is provided above select gate electrode SG. Source line SL and contact electrode 42 are provided above interlayer insulating film 20. Interlayer insulating film 22 is provided around source line SL. Source line SL is shaped like a belt extending along the X direction as viewed in the figures (the front and rear direction extending into the page of FIG. 2).

Interlayer insulating film 24 is provided above source line SL. Bit line BL is provided above interlayer insulating film 24. Bit line BL is shaped like a belt extending along the Y direction as viewed in the figures (the left and right direction as viewed in FIG. 2). A silicon oxide film for example may be used as interlayer insulating film 20, 22, and 24.

Select gate insulating film SGI is provided between select gate electrode SG and semiconductor pillar SP. A stack film, having silicon oxide film/silicon nitride film/silicon oxide film may be used as select gate insulating film SGI. The film used in pillar insulating film 28 may be used for select gate insulating film SGI.

Select gate transistor is formed at a portion where select gate electrode SG and semiconductor pillar SP intersect. Select gate transistor uses select gate insulating film SGI as a gate oxide film and serves as a MOS transistor in which semiconductor pillar SP serves as a channel portion. Further, select gate transistor serves as a switching transistor configured to select memory string MS.

The upper portions of semiconductor pillars SP2 and SP3 are connected to source line SL via pillar contact portion 40. Source-side select gate electrode SG (SGS) is disposed around semiconductor pillar SP2 and SP3 located between source line SL and electrode film 604 in the uppermost layer.

The upper portions of semiconductor pillars SP1 and SP4 are connected to bit line BL via pillar contact portion 40 and contact electrode 42. Drain-side select gate electrode SG (SGD) is disposed around semiconductor pillar SP1 and SP4 located between bit line BL and electrode film 604 in the uppermost layer.

Isolation insulating film ILP1 is provided between semiconductor pillars SP1 and SP2 which are connected at their lower portions by connecting portion SC1. Isolation insulating film ILP1 isolates or divides select gate electrodes SG and electrode films 60 located between semiconductor pillars SP1 and SP2 in the Y direction (the left and right direction as viewed in FIG. 2).

Isolation insulating film ILP1 is provided between semiconductor pillars SP3 and SP4 which are connected at their lower portions by connecting portion SC2. Isolation insulating film ILP1 isolates select gate electrodes SG and electrode films 60 located between semiconductor pillars SP3 and SP4 in the Y direction (the left and right direction as viewed in FIG. 2).

Isolation insulating film ILP1 extends through stopper film 16 to reach the surface of back gate BG (BG2) located below stopper insulating film 16. The bottom portion of isolation insulating film ILP1 is provided so as to form a trench in the upper surface of back gate BG (BG2). The position of the bottom surface of isolation insulating film ILP1 is specified at a position lower in the Z direction as viewed in the figures than the position of the upper surface of back gate BG (BG2).

Isolation insulating film ILP1 extends along the X direction (the front and rear direction extending into the page of FIG. 2). Metal silicide layer 72 is formed along the side surface portions of select gate electrode SG and electrode film 604 that contact (face) isolation insulating film ILP1. Metal silicide layer 72 is formed along the portion of back gate BG (BG2) that contact isolation insulating film ILP1. Metal silicide layer 72 extends along the X direction (the front and rear direction extending into the page of FIG. 2) along isolation insulating film ILP1. Various metal silicides maybe used as metal silicide layer 72 such as nickel silicide (NiSi), cobalt silicide (CoSi), titanium silicide (TiSi), tungsten silicide (WSi), molybdenum silicide (MoSi), or the like.

As described above, it is possible to reduce the resistance of select gate electrodes SG and electrode films 60 by metal silicide layers 72 formed along the side surfaces of electrode films 60 (601 to 604) and select gate electrodes SG contacting isolation insulating films ILP1.

Further, metal silicide layers 72 are formed in the upper surfaces of back gates BG (BG2) contacting isolation insulating films ILP1. It is thus, possible to reduce the resistance of back gate BG.

Isolation insulating film ILP2 is provided between adjacent semiconductor pillars SP2 and SP3 which are not connected by connecting portion SC. Isolation insulating film ILP2 isolates select gate electrodes SG located between semiconductor pillars SP2 and SP3 in the Y direction (the left and right direction as viewed in FIG. 2). Isolation insulating film ILP2 extends along the X direction (the front and rear direction extending into the page of FIG. 2). Isolation insulating film ILP2 is provided so as to reach the upper surface of interelectrode insulating film 62 located between select gate electrode SG and electrode film 604 in the uppermost layer. Isolation insulating film ILP2 isolates the select gate electrodes SG located between the adjacent memory cell strings MS in the Y direction (the left and right direction as viewed in FIG. 2).

Metal silicide layer 72 is formed along the side surface portion of select gate electrode SG being isolated by isolation insulating film ILP2 and contacting (facing) isolation insulating film ILP2. Metal silicide layer 72 extends along isolation insulating film ILP2 and along the X direction (the front and rear direction extending into the page of FIG. 2). It is thus, possible to further reduce the resistance at this portion of select gate electrode SG.

As described above, the resistance of select gate electrodes SG and electrode films 60 is reduced in the present embodiment by metal silicide layers 72 formed along the side surface portions of electrode films 60 (601 to 604) and select gate electrodes SG. It is thus, possible to reduce the drive voltage of nonvolatile semiconductor device 10 and accelerate the operation of nonvolatile semiconductor device 10.

Further, in the present embodiment, metal silicide layers 72 are formed in the upper surface portion of back gate BG2 contacting isolation insulating film ILP1. It is thus, possible to reduce the resistance of back gate BG and consequently reduce the drive voltage of nonvolatile semiconductor device 10 and accelerate the operation of nonvolatile semiconductor device 10.

### Manufacturing Method

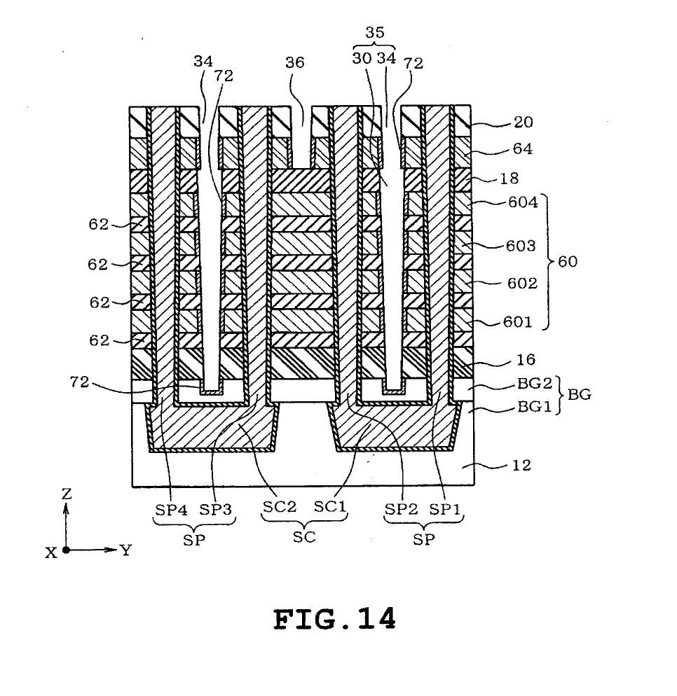

Next, a manufacturing method of nonvolatile semiconductor storage device 10 of the present embodiment will be described with reference to FIG. 2 to FIG. 14. FIG. 2 to FIG. 14 are examples of vertical cross-sectional views for presenting the manufacturing method of nonvolatile semiconductor storage device 10 of the present embodiment and are examples of vertical cross-sectional views schematically illustrating the structure taken along line A-A of FIG. 1 according to the process flow.

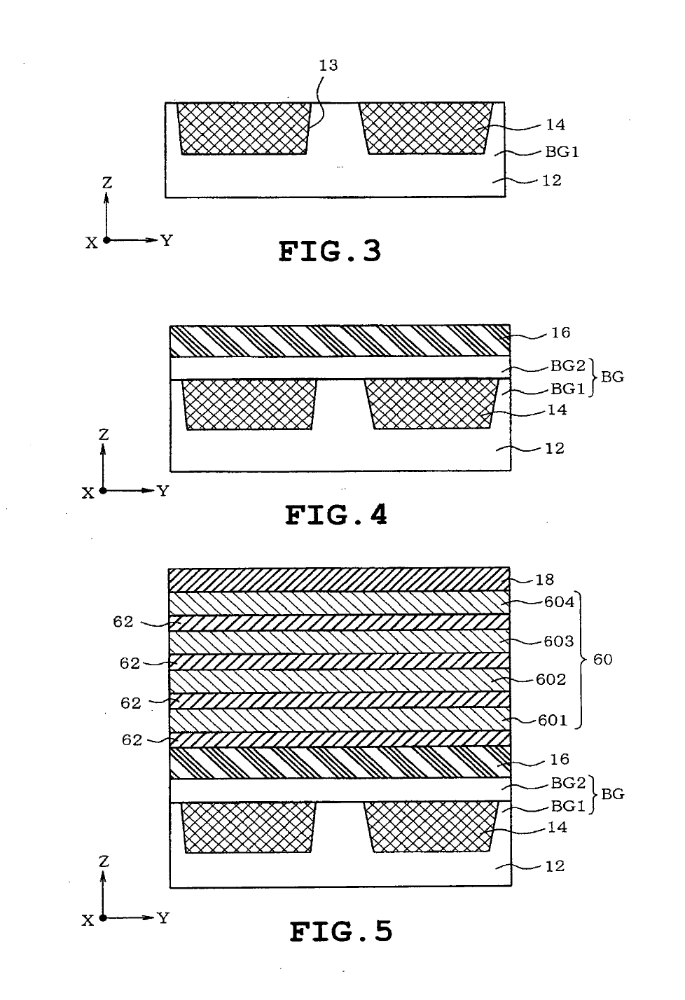

First, first back gate BG1 is formed in semiconductor substrate 12 as illustrated in FIG. 3. A silicon substrate may be used for example as semiconductor substrate 12. Back gate BG1 may be formed for example by introducing boron impurities into the silicon substrate.

Then, trenches 13 are formed into back gate BG1 by lithography and RIE (Reactive Ion Etching). Trenches 13 are rectangular in plan view and later become connecting portions SC.

Further, semiconductor substrate 12 being used may be prepared for example by forming elements such as transistors, which are components of a peripheral circuit, in a silicon substrate and thereafter covering the upper portions of the elements by an insulating film. After planarizing the upper surface of the insulating film, an amorphous silicon film doped with boron for example may be formed above the insulating film. In such case, the amorphous silicon film serves as back gate BG1 in which trenches 13 are formed.

Next, trenches 13 are filled with sacrificial film 14. A non-doped silicon free of impurities for example may be used as sacrificial film 14. CVD (Chemical Vapor Deposition) may be used for forming silicon such as an amorphous silicon.

Then, second back gate BG2 is formed above the upper surface of back gate BG1 and sacrificial film 14 as illustrated in FIG. 4. An amorphous silicon film doped with boron may be used for example as back gate BG2. The amorphous silicon film may be formed for example by CVD.

Then, stopper insulating film 16 is formed above back gate BG2. Tantalum oxide (TaO) may be used for example as stopper insulating film 16. Tantalum oxide may be formed for example by sputtering.

Tungsten silicide (WSi), alumina (AlO), aluminum nitride (AlN), hafnium oxide (HfO), boron nitride (BN), titanium oxide (TiO), or the like may be used as stopper insulating film 16 instead of tantalum oxide. Stopper insulating film 16 serves as an etch stopper when forming through hole 26 later in the process flow.

Next, interelectrode insulating film 62 and electrode film 60 are formed repeatedly above stopper film 16 as illustrated in FIG. 5. A silicon oxide film for example may be used as interelectrode insulating film 62. The silicon oxide film may be formed for example by CVD. An amorphous silicon may be used as electrode film 60. The amorphous silicon may be formed for example by CVD. Electrode film 60 is rendered electrically conductive by introducing impurities. Boron impurities may be used for example. For example, an amorphous silicon doped with impurities maybe formed by introducing boron in-situ during CVD film formation.

In the example of the present embodiment, four layers of electrode films 60, namely electrode film 601, 602, 603, and 604, are formed from stopper insulating film 16 side. Any number of electrode films 60 maybe stacked as mentioned earlier and thus, not limited to four layers. Interlayer insulating film 18 is formed above the uppermost electrode film 604. A silicon oxide film may be used for example as interlayer insulating film 18. The silicon oxide film may be formed for example by CVD.

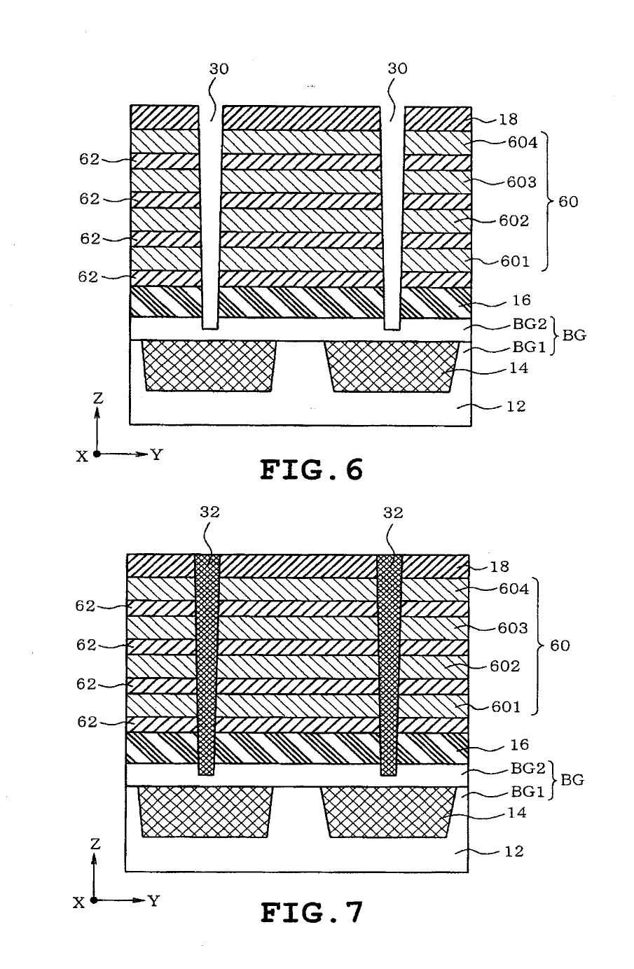

Next, first isolation trenches 30 are formed which extend from the upper surface of interlayer insulating film 18 to the upper surface of back gate BG2 as illustrated in FIG. 6. First isolation trenches 30 may be formed by lithography and RIE. First isolation trenches 30 are formed above the central portion as viewed in the Y direction (the left and right direction as viewed in the figures) of the region where sacrificial film 14 is formed. First isolation trenches 30 extend in the X direction (the front and rear direction extending into the page of FIG. 2).

In the RIE etching, a condition may be applied in which the difference of the etch rates of interlayer insulating film (a silicon oxide film for example), electrode film 60 (amorphous silicon for example), and interelectrode insulating film 62 (a silicon oxide film for example) are small. Further, in the RIE etching, a condition may be applied in which the etch rates of interlayer insulating film 18 (a silicon oxide film for example), electrode film 60 (amorphous silicon for example), and interelectrode insulating film 62 (a silicon oxide film for example) are higher as compared to the etch rate of stopper insulating film 16 (tantalum oxide film for example). Thus, the formation of first isolation trenches 30 stops on stopper insulating film 16.

Next, stopper insulating film 16 is etched after changing the etching conditions so that the etch rate of stopper insulating film 16 is higher than the etch rate of back gate BG2 (amorphous silicon for example). The etching of stopper insulating film 16 stops on the upper surface of back gate BG. At this instance, a slight trenching (ploughing) of the surface of back gate BG2 caused by over etching is permissible. The etching is controlled so that first isolation trenches 30 do not extend through back gate BG2 and does not reach sacrificial film 14.

Next, first isolation trenches 32 are filled with sacrificial film 32 as illustrated in FIG. 7. A silicon nitride film (SiN) may be used for example as sacrificial film 32. The silicon nitride film may be formed for example by CVD. The silicon nitride film filling first isolation trenches 30 and further covering the upper surface of interlayer insulating film 18 is thereafter subjected to CMP (Chemical Mechanical Polishing) or etched back by RIE. The silicon nitride film formed above the upper surface of interlayer insulating film 18 is thus, removed.

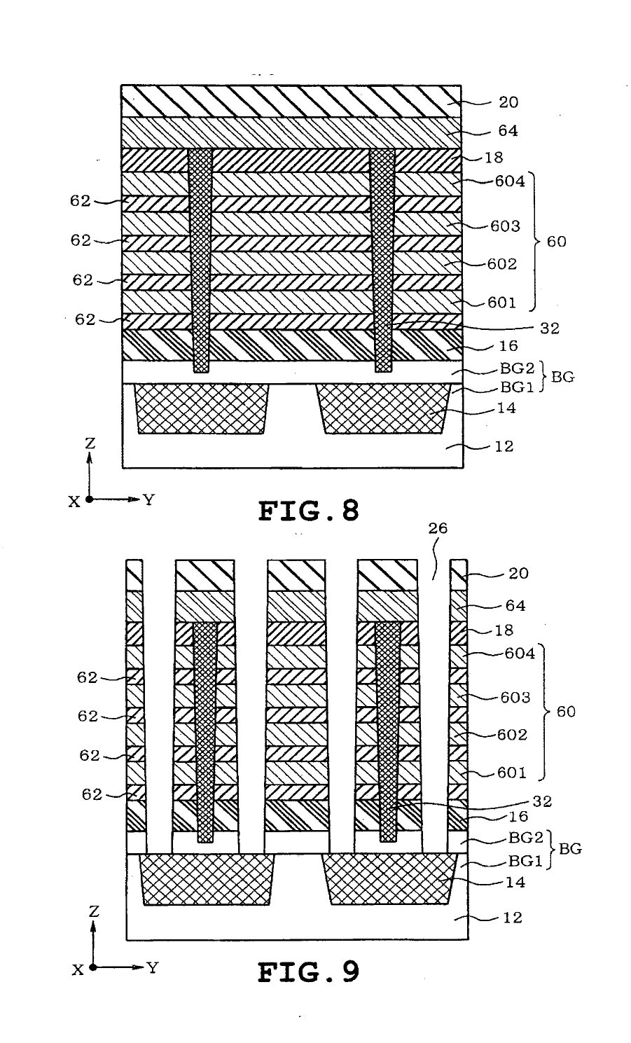

Next, electrode film 64 and interlayer insulating film 20 is formed as illustrated in FIG. 8. An amorphous silicon may be used as electrode film 64. The amorphous silicon may be formed for example by CVD. Electrode film 64 is rendered electrically conductive by introducing impurities for example. Boron may be used as impurities. An amorphous silicon doped with impurities may be formed for example by introducing boron in-situ during CVD film formation. Electrode film 64 later becomes select gate electrode SG. A silicon oxide film may be used for example as interlayer insulating film 20. The silicon oxide film may be formed for example by CVD.

Next, through holes 26 extending through the surface of interlayer insulating film 20 and through the upper surface of sacrificial film 14 is formed as illustrated in FIG. 9. Through holes 26 are formed so as to be located on both sides of sacrificial film 32 and so as to connect to both Y direction ends of sacrificial film 14. Through holes 26 may be formed by lithography and RIE. In the RIE etching, etching conditions may be applied in which the difference between the etch rates of interlayer insulating film 20, electrode film 64, interlayer insulating film 18, interelectrode insulating film 62, and electrode film 60 are small. That is, etching conditions may be applied in which the difference between the etch rates of a silicon oxide film and silicon (amorphous silicon) are small. The etching allows the stack of interlayer insulating film 20, electrode film 64, interlayer insulating film 18, interelectrode insulating film 62, and electrode film 60 to be etched at once.

Further, in the RIE etching, etching conditions may be applied in which the etch rate of stopper insulating 16 is small. That is, it is possible to apply etching conditions having etch selectivity to stopper insulating film 16. It is possible to stop through holes 26 on the surface of stopper insulating film 16.

Next, etching is performed after changing the etching conditions so that the etch rate of back gate BG2 (amorphous silicon for example) is lower than the etch rate of stopper insulating film 16 (tantalum oxide for example). In other words, etching is performed after changing the etching conditions so as to possess etch selectivity to back gate BG. This causes the etching of stopper insulating film 16 to progress and stop on back gate BG.

Next, etching is performed after changing the etching conditions for etching back gate BG (amorphous silicon) and specifying the time for etching away the amount corresponding to the thickness of the upper portion (that is, back gate BG2) of back gate BG. Thus, back gate BG2 in the lower portion of through holes 26 are etched to expose the upper surface of sacrificial film 14. At this instance, a slight trenching (ploughing) of the upper surface of sacrificial film 14 is permissible.

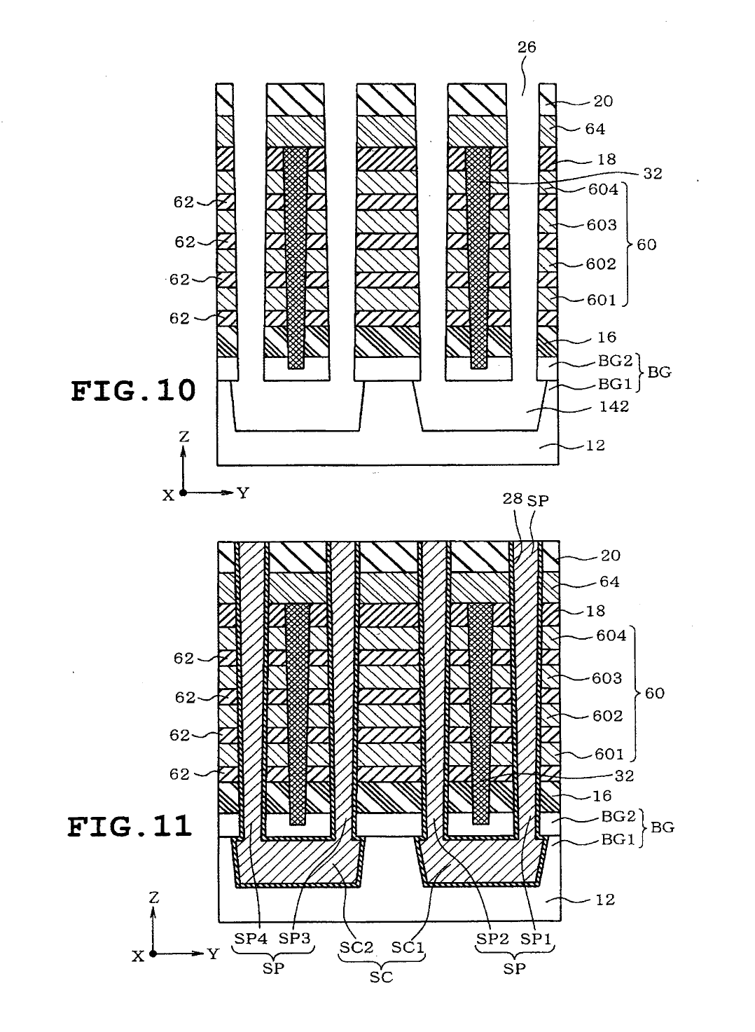

Next, sacrificial film 14 is removed by etching as illustrated in FIG. 10. A treatment with alkaline chemical liquid for example may be used for removing sacrificial film 14 by etching. It is thus, possible to selectively remove sacrificial film 14. This process step allows formation of a structure in which adjacent through holes 26 are connected through space 142 defined after removing sacrificial film 14.

Next, pillar insulating film 28 and semiconductor pillar SP are formed inside through holes 26 and spaces 142 as illustrated in FIG. 11. A stack film of first silicon oxide film (SiO₂)/silicon nitride film (SiN)/second silicon oxide film (SiO₂) may be used for example as pillar insulating film 28. First silicon oxide film, silicon nitride film, and second silicon oxide film may be formed for example by CVD.

A semiconductor film may be used for example as semiconductor pillar SP. An amorphous silicon may be used for example as the semiconductor film. The amorphous silicon may be formed for example by CVD. As a result, through holes 26 and spaces 142 are filled with films formed in the sequence of first silicon oxide film, silicon nitride film, and second silicon oxide film towards the center from the sidewall side of through holes 26. Connecting portions SC are formed by filing spaces 142, formed by removing sacrificial film 14, with the amorphous silicon formed when forming pillar insulating film 28 and semiconductor pillar SP. The central portions of through holes 26 and spaces 142 may be a void or may be filled with an additionally formed insulating film (a silicon oxide film for example.)

Pillar insulating film 28 and semiconductor pillar SP formed above interlayer insulating film 20 may be removed by etch back performed by RIE etching. Semiconductor pillars SP are represented as SP1, SP2, SP3, and SP4 from the Y direction right side of the figures. The portion connecting the lower portions of semiconductor pillars SP1 and SP2 are represented as connecting portion SC (SC1). Similarly, the portion connecting the lower portions of semiconductor pillars SP3 and SP4 are represented as connecting portion SC (SC2).

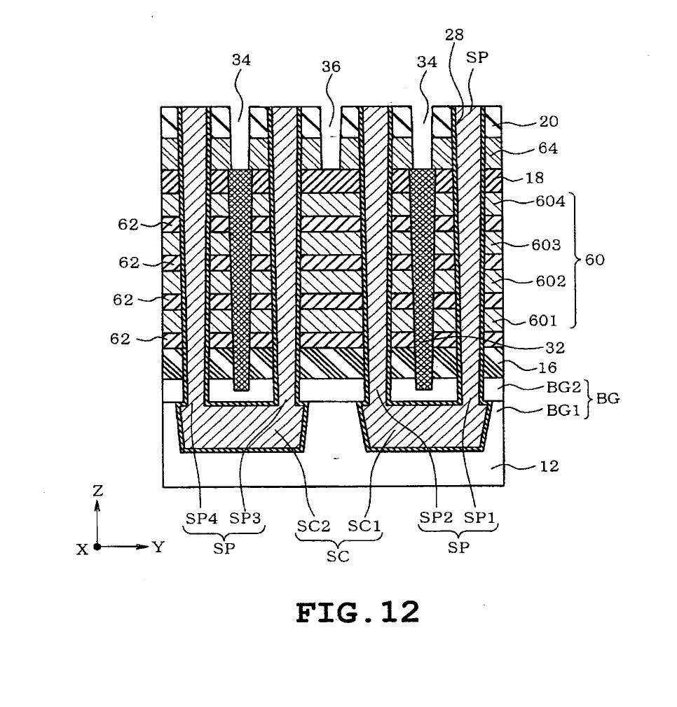

Next, second isolation trenches 34 and third isolation trench 36 are formed as illustrated in FIG. 12. Second isolation trenches 34 and third isolation trench 36 are formed by lithography and RIE. Second isolation trenches 34 and third isolation trench 36 are formed so as to extend from the upper surface of interlayer insulating film 20 to the upper surface of interlayer insulating film 18 located below electrode films 64. Second isolation trenches 34 and third isolation trench 36 are formed so as to extend through electrode films 64 (select gate electrodes SG).

Second isolation trenches 34 are formed so as to isolate or divide electrode films 64 (select gate electrodes SG) located between semiconductor pillars SP1 and SP2 connected by connecting portion SC1 and between semiconductor pillars SP3 and SF4 connected by connecting portion SC2. Third isolation trench 36 is formed so as to isolate electrode films 64 (select gate electrodes SG) located between semiconductor pillars SP2 and SP3 not connected by connecting portion SC. Second isolation trenches 34 and third isolation trench 36 extend in the X direction as viewed in the figures (the front and rear direction extending into the page of FIG. 2).

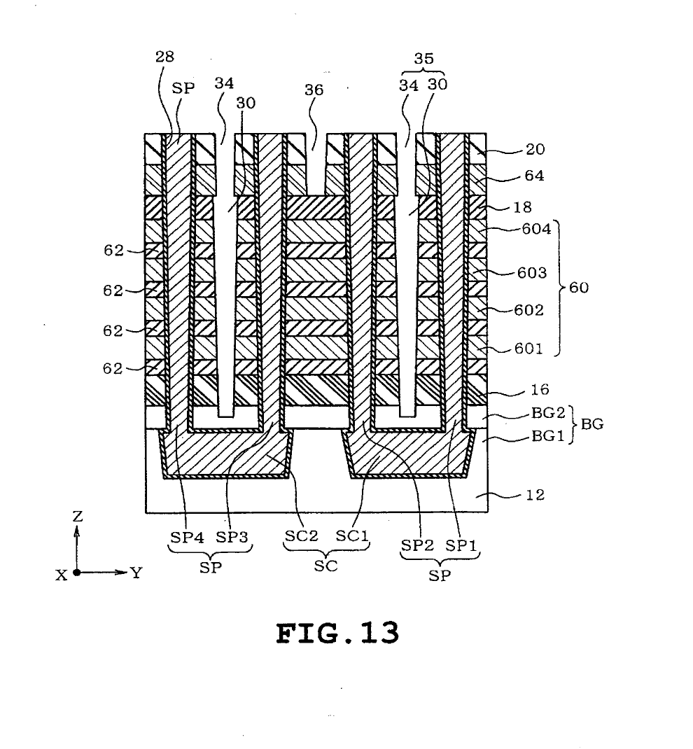

Next, sacrificial film 32 (a silicon nitride film for example) is removed as illustrated in FIG. 13. Sacrificial film 32 may be removed by using hot phosphoric acid for example. As a result, first isolation trenches 30 and second isolation trenches 34 become connected to form continuous isolation trenches 35. Back gate BG (BG2) is exposed at the bottom portions of isolation trenches 35 formed by first isolation trenches 30 and second isolation trenches 34.

Side surfaces of electrode films 60 and electrode films 64 are exposed as the inner wall surfaces of isolation trenches 35. Side surfaces of electrode films 64 are exposed as the inner wall surface of third isolation trench 36. The lower portion of third isolation trench 36 extends along the surface of interlayer insulating film 18.

Next, metal silicide layers 72 are formed along the portions of electrode films 60 (word lines WL) and electrode films 64 (select gate electrodes SG) exposed as the inner wall of isolation trenches 35 and third isolation trench 36. Metal silicide layers 72 are formed by the following process steps. First, metal film is formed inside isolation trenches 35 and third isolation trench 36. Nickel (Ni) may be used for example as the metal film. Cobalt (Co), titanium (Ti), tungsten (W), or molybdenum (Mo) may be used for example instead of nickel. Nickel may be formed for example by CVD. Annealing is performed after nickel is formed. For example, annealing may be performed in a mixed atmosphere of hydrogen and oxygen at a temperature ranging from 300 degrees Celsius to 600 degrees Celsius.

The annealing forms metal silicide layers 72 (nickel silicides in the present embodiment) in the portions where the metal film contacts electrode films 60 (word lines WL), where the metal film contacts electrode films 64 (select gate electrodes SG), and where the metal film contacts back gate BG. In other words, metal silicide layers 72 are formed along the side surfaces of electrode films 64 (select gate electrodes SG) and electrode films 60 (word lines WL) being isolated by isolation trenches 35 in the portions located between semiconductor pillars SP1 and SP2 and between semiconductor pillars SP3 and SP4. Metal silicide layers 72 are formed at portions facing the trenches formed into the uppers surface of back gate BG (BG2) in the bottom portions of isolation trenches 35. Metal silicide layers 72 are formed along the side surfaces of electrode films 64 (select gate electrodes SG) isolated by third isolation trench 36 in the portion located between semiconductor pillars SP2 and SP3.

Then, metal film (excess metal) unreacted in the annealing is removed. The excess metal may be removed for example by peroxodisulfate aqueous solution (a mixed solution of sulfuric acid and hydrogen peroxide water).

Next, isolation trenches 35 formed by first isolation trenches 30 and second isolation trenches 34 are filled with isolation insulating film ILP1, and third isolation trench 36 is filled with isolation insulating film ILP2 as illustrated in FIG. 2. Isolation insulating films ILP1 and ILP2 may be formed of for example an insulating film. A silicon oxide film may be used for example as an insulating film and may be formed for example by CVD. Isolation insulating films ILP1 and ILP2 may be formed by filling isolation trenches 35 and third isolation trench 36 with the insulating film and polish removing the insulating film formed above the upper surface of interlayer insulating film 20 by CMP (Chemical Mechanical Polishing). It is permissible for the upper portions of interlayer insulating film 20 and semiconductor pillar SP to be slightly polished by CMP.

As described above, first isolation trenches 30 communicating with second isolation trenches 34 form isolation trenches 35. Isolation trenches 35 are filled with an insulating film to form isolation insulating film ILP1. Third isolation trench 36 is filled with an insulating film to form isolation insulating film ILP2.

Then, pillar contact portions 40, interlayer insulating film 22, source line SL, interlayer insulating film 24, contact electrodes 42, and bit line BL are formed one after another. It is possible to form nonvolatile semiconductor storage device 10 of the present embodiment by the above described process steps.

As described above, the present embodiment allows the resistance of select gate electrodes SG and electrode films 60 to be reduced by metal silicide layers 72 formed along the side surface portions of electrode films 60 (601 to 604) and along the side surface portions of select gate electrodes SG contacting isolation insulating film ILP1 and isolation insulating film ILP2.

Further, the present embodiment allows the resistance of back gate BG to be reduced by metal silicide layers 72 formed along the surface of back gate BG (BG2) contacting the bottom portions of isolation insulating films ILP1.

As a result, it is possible to reduce the drive voltage of nonvolatile semiconductor storage device 10 and accelerate the operation of nonvolatile semiconductor storage device 10.

The embodiment described above may be applied to a NAND type or a NOR type flash memory, EPROM, EEPROM, or other types of nonvolatile semiconductor storage devices.

While certain embodiments have been described, these embodiments have been presented by way of example only, arid are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a semiconductor substrate;
a stack structure disposed above the semiconductor substrate and including a plurality of insulation layers and conductive layers stacked alternatively above one another;
a select gate electrode layer disposed above the stack structure;
a plurality of holes extending through the stack structure and the select gate electrode layer;
a connecting portion connecting lower portions of adjacent holes among the plurality of holes;
a pillar insulating film and semiconductor pillars disposed in the holes being connected by the connecting portion and in the connecting portion;
a back gate disposed between a portion above the connecting portion and the stack structure;
an isolation trench disposed between the semiconductor pillars being adjacent to and connected to one another so as to isolate the stack structure and the select gate electrode layer, the isolation trench having a bottom portion contacting the back gate, a bottom surface of the isolation trench being lower than an upper surface of the back gate; and
a metal silicide disposed in a portion where the back gate contacts the isolation trench.

2. The device according to claim 1, wherein the bottom portion of the isolation trench does not contact the pillar insulating film of the connecting portion.

3. The device according to claim 1, wherein the semiconductor pillars comprise silicon.

4. The device according to claim 1, wherein the conductive layers and the select gate electrode layer comprise silicon.

5. The device according to claim 1, further comprising a metal silicide formed along side surfaces of the conductive layers and the select gate electrode layer contact the isolation trench.

6. The device according to claim 1, wherein the isolation trench is filled with an insulating film.

7. The device according to claim 6, wherein the insulating film filling the trench contacts the metal silicide.

8. The device according to claim 1, wherein the metal silicide includes at least either of nickel, cobalt, titanium, tungsten, and molybdenum.

9. A nonvolatile semiconductor storage device comprising:
a semiconductor substrate;
a stack structure disposed above the semiconductor substrate and including a plurality of insulation layers and conductive layers stacked alternatively above one another;
a select gate electrode layer disposed above the stack structure;
a plurality of holes extending through the stack structure and the select gate electrode layer;
a connecting portion connecting lower portions of adjacent holes among the plurality of holes;
a pillar insulating film and semiconductor pillars disposed in the holes being connected by the connecting portion and in the connecting portion;
a back gate disposed between a portion above the connecting portion and the stack structure;
a first isolation trench disposed between the semiconductor pillars being adjacent to and connected to one another so as to isolate the stack structure and the select gate electrode layer, the first isolation trench having a bottom portion contacting the back gate, a bottom surface of the first isolation trench being lower than an upper surface of the back gate;
a first metal silicide disposed in a portion where the back gate contacts the first isolation trench;
a plurality of memory strings including a plurality of memory cells disposed at intersections of the semiconductor pillars and the conductive layers and select gate transistors disposed at intersections of the semiconductor pillars an the select gate electrode layer;
a second isolation trench disposed between the memory strings so as to isolate the select gate electrode layer; and
a second metal silicide disposed along side surfaces of select gate electrode layer contacting the second isolation trench.

10. The device according to claim 9, wherein the bottom portion of the second isolation trench does not contact an uppermost conductive layer of the conductive layers.

11. The device according to claim 9, further comprising storage layers disposed between the semiconductor pillars and the conductive layers.

12. The device according to claim 9, wherein the semiconductor pillars comprise silicon.

13. The device according to claim 9, wherein the conductive layers and the select gate electrode layer comprise silicon.

14. The device according to claim 9, further comprising a third metal silicide formed along side surfaces of the conductive layers and the select gate electrode layer contacting the first isolation trench.

15. The device according to claim 9, wherein the first isolation trench is filled with an insulating film.

16. The device according to claim 9, wherein the second isolation trench is filled with an insulating film.

17. The device according to claim 15, wherein the insulating film filling the first isolation trench contacts the first metal silicide.

18. The device according to claim 16, wherein the insulating film filling the second isolation trench contacts the second metal silicide.

19. The device according to claim 9, wherein the first metal silicide and the second metal silicide include at least either of nickel, cobalt, titanium, tungsten, and molybdenum.
